(19) United States
(12) Patent Application Publication
(10) Pub. No.: US 2008/0014406 A1
(43) Pub. Date: Jan. 17, 2008

(54) Injection molded soldering head for high temperature application and method of making same

(75) Inventors: S. Jay Chey, Ossining, NY (US); Peter A. Gruber, Mohegan Lake, NY (US)

Correspondence Address: MICHAEL J. BUCHENHORNER, 8540 S.W. 83 STREET, MIAMI, FL, 33143, US

(73) Assignee: International Business Machines Corporation

(21) Appl. No.: 11/484,124

(22) Filed: Jul. 11, 2006

(51) Int. Cl. C23C 16/00; B32B 3/10

(52) U.S. Cl. 428/131; 427/249.7

(57) ABSTRACT

An injection molded soldering head includes a substrate that is flexible (compliant) and stable at high temperature. The substrate includes an aperture therethrough for holding and dispensing solder onto a mold and a low friction coating on the bottom side of the substrate to provide a lower friction surface for the head.

### CROSS-REFERENCE TO RELATED APPLICATIONS

Not Applicable.

### STATEMENT REGARDING FEDERALLY SPONSORED-RESEARCH OR DEVELOPMENT

Not Applicable.

### INCORPORATION BY REFERENCE OF MATERIAL SUBMITTED ON A COMPACT DISC

Not Applicable.

### FIELD OF THE INVENTION

The invention disclosed broadly relates to the field of injection molded soldering (IMS), and more particularly relates to the field of injection molded soldering heads for high temperature application.

### BACKGROUND OF THE INVENTION

Injection molded soldering (IMS), also known as C4NP (C4 New Process) when used for C4 (controlled collapse chip connections bumping, is increasingly used in the semiconductor industry as a method of plating C4 solder bumps onto wafers or modules. The IMS technology was invented and developed at IBM Research. IMS works by injecting molten solder into molds with the desired C4 dimensions, then transferring those C4 onto the wafers or modules. Most of the technology involves the scanning head. The scanning head consists of the reservoir containing the molten solder and the solder injection aperture. The part with the solder injection aperture requires careful engineering for optimal solder filling into the C4 cavities without any solder leakage or solder defects.

The main advantage of IMS is that there is no need to develop individual recipes for plating as you change the components of the solder material. The material which forms the solder injection aperture for IMS used to fill molten solder need to have characteristics of thermal stability, compliance, and low friction. Typically, for eutectic solder or other low temp solders, compliant materials such as a fluorocarbon (such as that sold under the trademark Rulon®) are used. Also, a material such as an elastomer or fluoropolymer elastomer, or simply fluoroelastomer, (commonly sold under the trademark Viton® used for O-rings) is used on certain applications. The problem with most polymers or elastomers is that they are not thermally stable at high temperature. Typically, above degrees 260 C these materials either melt or decompose. Material such as polyimide or polyimide film are stable up to 400 degrees C. but the coefficient of friction is high (typically 0.6) which makes it difficult to scan smoothly over flat surfaces such as silicon or glass.

Graphite has an extremely low coefficient of friction (0.1) but is not compliant so any protrusion or non-flatness on the scanning surface might cause leakage of solder while dispensing the solder. The challenge is to discover and use a material that satisfies the above criteria and is also economical to manufacture. Therefore, there is a need for a solution that overcomes the above shortcomings of the prior art.

### SUMMARY OF THE INVENTION

Briefly, according to an embodiment of the invention, an injection molded soldering head includes a substrate that is flexible (compliant) and stable at high temperature. The substrate includes an aperture (such as a slot) therethrough, for holding and dispensing solder onto a mold, and a low friction coating on the substrate to provide a lower friction surface for the head.

According to another embodiment of the invention, a method includes steps of coating a flexible layer with a thin coating of a low friction material to provide a lower surface for the head. The low friction material may be a Diamond like carbon or amorphous carbon.

In another embodiment, polyimide film may be used as the substrate because it offers good thermal stability and compliance and because it is easily laminated to head base plates. Diamond-like-carbon (DLC) or amorphous carbon is a material known to have low friction.

In another embodiment of the invention the low friction coating is applied to any compliant material which requires a lower friction. The low friction coating is thin enough so that it does not interfere with the polymer's original properties such as compliance, thermal stability or vacuum sealing ability.

### BRIEF DESCRIPTION OF THE DRAWINGS

FIG. 1 is a side view of an amorphous carbon coated polyimide film layer used in an IMS head.

FIG. 2A is a side view of an IMS head with amorphous carbon coated polyimide film used as the solder injection aperture assembly.

FIG. 2B is a bottom view of an IMS head with amorphous carbon coated polyimide film used as the solder injection aperture assembly.

FIG. 3 is a schematic of an IMS head with amorphous carbon coated polyimide laminated on a thin flexible metal sheet used as the solder injection aperture assembly.

FIG. 4A is a schematic of a bottom view of an O-ring sealed IMS head.

FIG. 4B is a schematic of a side view of an O-ring coated with amorphous carbon film.

### DETAILED DESCRIPTION

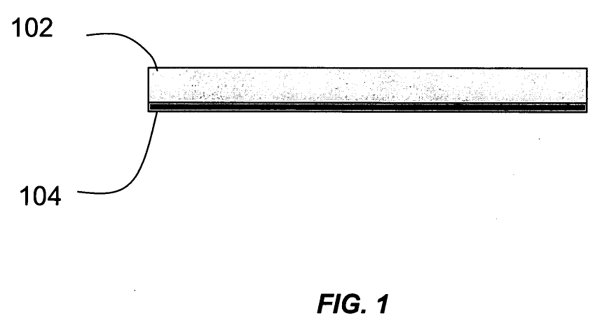

FIG. 1 is a side view of a part of an IMS head according to an embodiment of the invention. A polyimide film layer (such as Kapton® polyimide film) 102 is coated with an amorphous carbon layer 104. The amorphous carbon layer 104 may be deposited by plasma sputter deposition, laser ablation, ion beam assisted deposition, direct ion beam deposition, ion beam sputter deposition, plasma enhanced CVD (chemical vapor deposition), or microwave ECR (Electron Cyclotron Resonance) CVD or other suitable processes. The thickness of the amorphous carbon layer 104 can be in the range of 50 to 2000 Angstroms. The optimal thickness of the amorphous carbon layer 104 is thick enough to provide the carbon characteristics of low friction, but not so thick as to cause cracking or delaminating due to thin film stress. The use of the above materials provides low friction sliding of the bottom surface of the head, while remaining stable at temperatures up to 400 degrees C., and providing compliance during the scanning of a surface which may have protrusions.

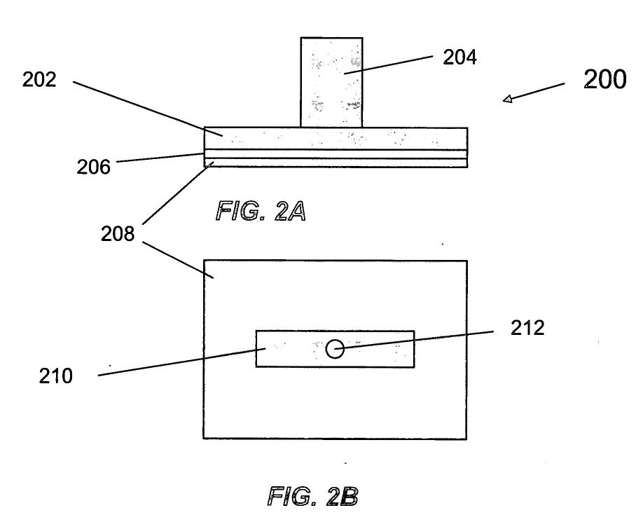

FIG. 2A is a side view of an IMS head 200 with a solder injection aperture 212. The IMS head 200 comprises a base plate 202, a solder reservoir 204, a polyimide film layer 206 (similar or identical to layer 102), and an amorphous carbon layer 208 (similar or identical to layer 104). The aperture 212 (shown in broken lines) leads to a slot 210 (also shown in broken lines) for holding solder to be dispensed on a circuit board surface. FIG. 2B is a bottom view of the IMS head 200. The part of the IMS head 200 with the aperture 212 is shown with the slot 210. The slot is formed through the polyimide film layer 206 and the amorphous carbon layer 208, exposing a part of the base plate 202 to the bottom of the head 200. This IMS head 200 is typically operated by the following method. The IMS head 200 sits on a mold with cavities which is to be filled with solder. The molten solder containing the IMS head 200 is scanned over the mold surface while pressure is applied to the solder reservoir. The solder is forced to flow through the small aperture 212 due to applied pressure from above and it fills the aperture area 210. The solder cannot escape from the aperture 210 until it encounters a cavity on the surface of the mold. As the aperture 210 of the IMS head 200 passes over the cavity in the mold, the solder is dispensed and fills the cavity. The friction during scanning is lowered by the low friction coating 208. In one embodiment, the amorphous carbon 208 is deposited by a RF (radio frequency) sputter deposition method. The polyimide film surface 206 is pre-treated by standard brush cleaning with a detergent followed by an oven bake at 140 degrees C. for two hours to bake out any water absorbed in the polyimide, then O2 plasma ash is applied to promote good adhesion. The Carbon deposition system is operated at 300 Watts for thirty minutes to degas the chamber. The RF power during deposition for the actual deposition is at 200 Watts. For this application, the system is operated for four hours to give an amorphous carbon thickness of about 500 Angstroms.

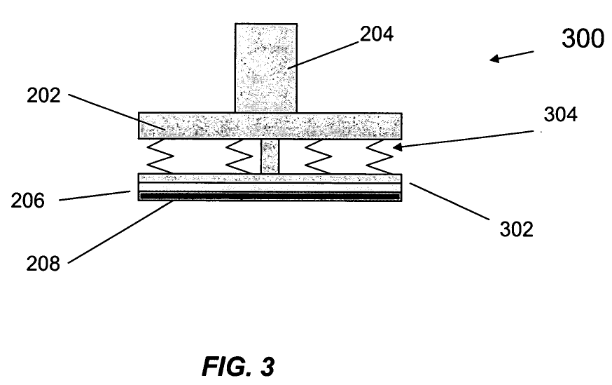

FIG. 3 is a schematic of an IMS head 300 similar to the one shown in FIG. 2, but with an additional feature of a thin flexible metal sheet 302 supporting the low friction thin film coated polyimide film sheet 206. The head 300 includes a set of springs 304 disposed between the base plate 202 and the thin flexible metal 304. The thin flexible metal sheet 304 provides additional compliance over a large area. The polyimide film layer 206 can be easily laminated onto the metal sheet. Details of a similar scheme is described in previous U.S. Pat. Nos. 6,056,191 and 6,527,158, which are hereby incorporated by reference.

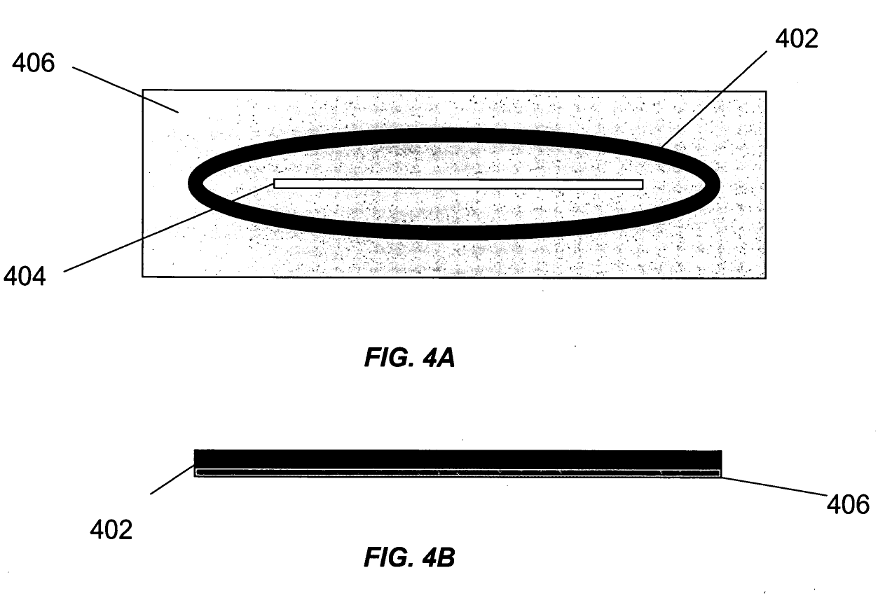

FIG. 4A is a schematic of a bottom view of a fluoroelastomer O-ring 402 sealed IMS head 400. The solder is dispensed from an aperture 404 (in the IMS head bottom plate assembly 406) and is contained within the O-ring 402. As the IMS head 400 scans over the mold, solder is injected into ariy cavities it passes over. FIG. 4B shows the O-ring 402 with a thin layer of amorphous carbon 406. The coating performed on the side where the O-ring 402 makes contact with the mold. Only one side is being deposited as that side is the sliding surface. In principle, the low friction coating 408 can be applied to the surface opposite of the O-ring surface, in this case, the mold surface. The situation (e.g., economics, durability etc) will dictate whether the O-ring 402 or mold gets coated. However, it is possible both sides receive the coating for minimizing the friction and wear. While fluoroelastomer is used for the O-ring in this embodiment, any compliant material with thermal stability can be used.

Therefore, while there has been described what is presently considered to be preferred embodiments, it will be understood by those skilled in the art that other modifications can be made within the spirit of the invention.

We claim:

1. An injection molded soldering head comprising:
a substrate that is compliant and stable at high temperature, the substrate comprising an aperture therethrough for holding and dispensing solder onto a mold, the substrate comprising a bottom surface and a top surface; and
a low friction coating on the bottom surface of the substrate to provide a lower friction surface for the head.

2. The injection molded soldering head of claim 1 wherein the substrate comprises a polyimide film material.

3. The injection molded soldering head of claim 1 wherein the low friction coating comprises amorphous carbon.

4. The injection molded soldering head of claim 1 further comprising a thin flexible metal sheet, located on the top surface of the substrate, used as a base plate for the head, the base plate comprising a solder injection aperture for the head.

5. The injection molded soldering head of claim 1 further comprising a solder reservoir located on the base plate for holding solder to be applied to a mold.

6. The injection molded soldering head of claim 4 wherein the solder injection aperture comprises a slot through which the solder is injected.

7. The injection molded soldering head of claim 4 further comprising an elastomer O-ring located on the bottom surface of the low friction coating and used as a solder seal for the solder injection aperture.

8. The injection molded soldering head of claim 1 further comprising:
a thin flexible metal layer over the substrate;
a base plate located over the thin flexible metal layer; and
one or more springs, disposed between the base plate and the thin flexible metal layer.

9. The injection molded soldering head of claim 7 wherein the O-ring is made from fluorocarbon.

10. The injection molded soldering head of claim 1 wherein the low friction coating comprises a Diamond-like-carbon (DLC) material.

11. A method of making an injection molded soldering head comprising: coating a flexible substrate with a low friction coating to provide a lower friction surface for the head.

12. The method of claim 11 wherein the step of coating comprises coating the substrate with an amorphous carbon material.

13. The method of claim 1 wherein the substrate is made from a polyimide film.

14. The method of claim 11 wherein the step of coating comprises coating the flexible surface with a Diamond-like-carbon material.

15. The method of claim 11 further comprising placing a base plate over the substrate.

16. The method of claim 15 further comprising placing a solder reservoir over the base plate.

17. The method of claim 11 further comprising making an aperture, in the flexible substrate and the low friction coating, for containing solder to be dispensed onto a mold.

18. The method of claim 15 further comprising adding a layer made from a thin flexible metal over the substrate and adding one or more springs disposed between the base plate and the substrate.

19. The method of claim 15 further comprising adding an O-ring on the bottom surface of the low friction coating.

20. The method of claim 19 where the O-ring is made from an elastomer.
